(19) United States
(12) Patent Application Publication
(10) Pub. No.: US 2016/0095224 A1
(43) Pub. Date: Mar. 31, 2016

(54) APPARATUS AND METHODS RELATED TO CERAMIC DEVICE EMBEDDED IN LAMINATE SUBSTRATE

(71) Applicant: SKYWORKS SOLUTIONS, INC., Woburn, MA (US)

(72) Inventor: Howard E. CHEN, Anaheim, CA (US)

(21) Appl. No.: 14/869,950

(22) Filed: Sep. 29, 2015

Related U.S. Application Data
(60) Provisional application No. 62/058,036, filed on Sep. 30, 2014.

(51) Int. Cl. H05K 1/18; H05K 7/02; H05K 3/30; H05K 1/11; H05K 3/46

(52) U.S. Cl. CPC H05K 1/183; H05K 1/115; H05K 3/4697; H05K 3/301; H05K 7/02; H05K 2201/10015; H05K 2201/1003

(57) ABSTRACT

Apparatus and methods related to ceramic device embedded in laminate substrate. In some embodiments, a laminate substrate can include a plurality of laminate layers, and a ceramic device having a first side and a second side, and embedded at least partially within the plurality of laminate layers. The ceramic device can include a conductive path between the first side and the second side. In some embodiments, such a laminate substrate can be utilized as a packaging substrate for a packaged module such as a radio-frequency (RF) module.

### CROSS-REFERENCE TO RELATED APPLICATION(S)

This application claims priority to U.S. Provisional Application No. 62/058,036 filed Sep. 30, 2014, entitled APPARATUS AND METHODS RELATED TO CERAMIC DEVICE EMBEDDED IN LAMINATE SUBSTRATE, the disclosure of which is hereby expressly incorporated by reference herein in its entirety.

### BACKGROUND

1. Field

The present disclosure relates to a laminate substrate having an embedded ceramic device.

2. Description of the Related Art

In many electronic applications, a laminate substrate can be utilized to mount various components thereon to form a packaged module. Such a module can include, for example, a radio-frequency (RF) module.

### SUMMARY

According to some implementations, the present disclosure relates to a laminate substrate that includes a plurality of laminate layers, and a ceramic device having a first side and a second side, and embedded at least partially within the plurality of laminate layers. The ceramic device includes a conductive path between the first side and the second side.

In some embodiments, the first and second sides of the ceramic device can face upper and lower sides of the plurality of laminate layers, respectively. The ceramic device can be a co-fired ceramic device such as a low-temperature co-fired ceramic (LTCC) device or a high-temperature co-fired ceramic (HTCC) device. The co-fired ceramic device can be configured as a ceramic substrate.

In some embodiments, the co-fired ceramic device can include a plurality of ceramic layers. The co-fired ceramic device can include more than two ceramic layers including an upper ceramic layer, a lower ceramic layer, and at least one intermediate ceramic layer, with the upper and lower ceramic layers facing the upper and lower sides of the plurality of laminate layers, respectively.

In some embodiments, the conductive path can include a conductive via that extends through all of the ceramic layers. In some embodiments, the conductive path can include a plurality of laterally offset conductive vias electrically connected by one or more conductive traces.

In some embodiments, the conductive path can be substantially within the ceramic device. The conductive path can be configured to facilitate an electrical connection between locations above and below the ceramic device without having to route the conductive path around the ceramic device. The locations above and below the ceramic device can include either or both of surface locations on the upper and lower sides of the plurality of laminate layers. The electrical connection between the locations above and below the ceramic device can include one or more conductive vias implemented through one or more of the plurality of laminate layers.

In some embodiments, the plurality of laminate layers can include a conductive path that bypasses the ceramic device. The conductive path bypassing the ceramic device can be configured to electrically connect respective locations on the upper and lower sides of the plurality of laminate layers. The conductive path bypassing the ceramic device can include a conductive via that extends through all of the plurality of laminate layers. The conductive path bypassing the ceramic device can include a plurality of laterally offset conductive vias electrically connected by one or more conductive traces.

In some embodiments, the ceramic device can include electrical connection features on both of the first and second sides. At least some of the electrical connection features on the first side of the ceramic device can be configured to facilitate a non-grounding connection. At least some of the electrical connection features on the second side of the ceramic device can be configured to facilitate a non-grounding connection. Two or more of the electrical connection features can be configured to facilitate an electrical connection between different locations on the ceramic device. The electrical connection between the different locations on the ceramic device further can include a conductive path through one or more of the plurality of laminate layers.

In some embodiments, the laminate substrate can be a packaging substrate configured to receive a plurality of components. Such a packaging substrate can be configured to be utilized to be part of a packaged module such as a radio-frequency (RF) module.

According to a number of teachings, the present disclosure relates to a panel for fabricating an array of radio-frequency (RF) modules. The panel includes a laminate substrate having a plurality of units configured to facilitate the fabrication of the array of RF modules. The laminate substrate further includes an embedded ceramic device at each of the plurality of units. The ceramic device includes an internal conductive path between its first and second sides.

In some implementations, the present disclosure relates to a radio-frequency (RF) module that includes a packaging substrate having a plurality of laminate layers and a ceramic device embedded at least partially within the plurality of laminate layers. The ceramic device includes an internal conductive path configured to facilitate an electrical connection between locations above and below the ceramic device without having to route the electrical connection around the ceramic device. The RF module further includes one or more RF components mounted on the packaging substrate.

In some embodiments, the ceramic device can further include a circuit configured to operate in conjunction with the one or more RF components. Such a circuit can include, for example, a filter circuit.

In some embodiments, the RF module can further include an overmold structure implemented over the packaging substrate. The overmold structure can be configured to encapsulate the one or more RF components. In some embodiments, the RF module can further include one or more RF shielding features implemented relative to the one or more RF components.

In a number of implementations, the present disclosure relates to a wireless device that includes a transceiver, and a radio-frequency (RF) module in communication with the transceiver and configured to process an RF signal. The RF module includes a packaging substrate having a plurality of laminate layers and a ceramic device embedded at least partially within the plurality of laminate layers. The ceramic device includes an internal conductive path configured to facilitate an electrical connection between locations above and below the ceramic device without having to route the electrical connection around the ceramic device. The RF module further includes one or more RF components mounted on the packaging substrate. The wireless device further includes an antenna in communication with the RF module and configured to facilitate transmission and/or reception of the RF signal.

According to some teachings, the present disclosure relates to a method for fabricating a laminate substrate. The method includes forming or providing a plurality of laminate layers having one or more regions, and embedding a ceramic device within the plurality of laminate layers at each of the one or more regions. The ceramic device includes an internal conductive path. The method further includes forming an electrical connection between locations above and below the ceramic device. The electrical connection includes the internal conductive path of the ceramic device.

In accordance with a number of implementations, the present disclosure relates to a method for fabricating a radio-frequency (RF) module. The method includes forming or providing a packaging substrate having a plurality of laminate layers and a ceramic device embedded at least partially within the plurality of laminate layers. The ceramic device includes an internal conductive path configured to facilitate an electrical connection between locations above and below the ceramic device without having to route the electrical connection around the ceramic device. The method further includes mounting one or more RF components on the packaging substrate.

In some embodiments, the method can further include forming an overmold over the packaging substrate to substantially encapsulate the one or more RF components. In some embodiments, the method can further include forming an RF shielding feature relative to the one or more RF components.

In a number of teachings, the present disclosure relates to a ceramic device that includes a stack of ceramic layers including an upper ceramic layer, a lower ceramic layer, and at least one intermediate ceramic layer. The upper and lower ceramic layers define upper and lower sides of the stack of ceramic layers, respectively. The ceramic device further includes a conductive path implemented between the upper and lower sides of the stack of ceramic layers.

In some embodiments, the ceramic device can further include a contact feature for each end of the conductive path. In some embodiments, the ceramic device can further include a filter circuit implemented between the upper and lower sides of the stack of ceramic layers.

In some implementations, the present disclosure relates to a method for fabricating a ceramic device. The method includes forming or providing ceramic layers, and arranging the ceramic layers to yield a stack having an upper ceramic layer, a lower ceramic layer, and at least one intermediate ceramic layer, with the upper and lower ceramic layers defining upper and lower sides of the stack, respectively. The method further includes implementing a conductive path between the upper and lower sides of the stack.

In some embodiments, the method can further include forming a contact feature for each end of the conductive path. In some embodiments, the method can further include implementing a filter circuit between the upper and lower sides of the stack.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows an example of a laminate substrate having a device embedded in one or more laminate layers.

FIG. 2 shows another example of a laminate substrate having a device embedded in one or more laminate layers.

FIG. 3 shows that in some embodiments, a laminate substrate can include a device embedded in one or more laminate layers.

FIG. 4 shows that in some embodiments, a low-temperature co-fired ceramic (LTCC) substrate can be configured to include one or more conductive paths between its upper and lower surfaces.

FIG. 5 shows that in some embodiments, an LTCC substrate can be configured to allow electrical connections on both of its sides.

FIG. 6 shows that in some embodiments, an LTCC substrate can be configured to include both functionalities associated with FIGS. 4 and 5.

FIG. 7 shows a radio-frequency (RF) module that includes a packaging substrate having one or more features as described herein.

FIG. 8 shows a process that can be implemented to fabricate a ceramic device such as an LTCC substrate having one or more features as described herein.

FIG. 9 shows a process that can be implemented to fabricate a laminate substrate having one or more features as described herein.

FIGS. 10A-10E show examples of various stages of the laminate substrate fabrication process of FIG. 9.

FIG. 11 shows an example RF module having a laminate substrate that can include a plurality of ceramic devices embedded therein.

FIG. 12 shows another example RF module having a laminate substrate that can include a plurality of ceramic devices embedded therein.

FIG. 13 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

Described herein are examples of apparatus and methods related to a ceramic device embedded in a laminate substrate. Although described in the context of ceramic devices and laminate substrates, it will be understood that one or more features of the present disclosure can also be implemented with other types of devices embedded in laminate substrates, ceramic devices embedded in other types of substrates, other types of devices embedded in non-laminate substrates, or any combination thereof.

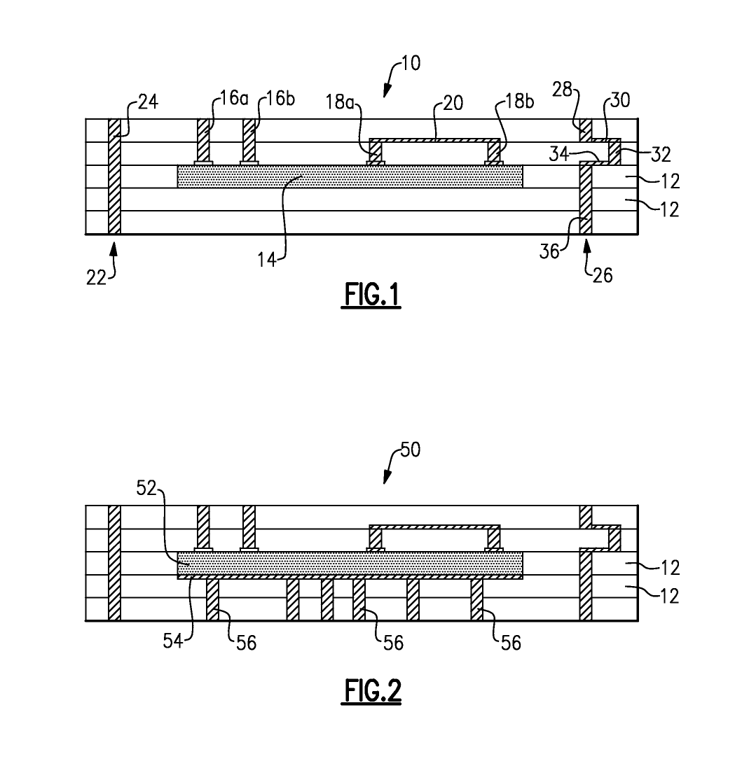

FIG. 1 shows an example of a laminate substrate 10 having a device 14 embedded in one or more laminate layers 12. Such a device (14) can be, for example, a semiconductor die (e.g., silicon or glass) based integrated passive device (IPD). In radio-frequency (RF) applications, such an IPD can include, for example, inductors and/or capacitors that are configured to yield a filter circuit.

The example embedded semiconductor die 14 of FIG. 1 is shown to include contact pads on one side (e.g., on the upper side when arranged as shown in FIG. 1). Such contact pads on the semiconductor die 14 can facilitate electrical connections between the upper surface of the semiconductor die 14 and locations on the upper surface of the laminate substrate 10 (e.g., through conductive vias 16a, 16b). The contact pads on the semiconductor die 14 can also facilitate one or more electrical connections between different locations on the semiconductor die 14. For example, conductive vias (18a, 18b) in a laminate layer and a conductive trace 20 can electrically connect two locations on the upper surface of the semiconductor die 14.

The laminate substrate 10 can also include one or more electrical conduction paths between the upper and lower surfaces of the laminate substrate 10. For example, a conductive through-substrate via 24 can provide an electrical connection between corresponding locations on the upper and lower surfaces of the laminate substrate 10. In another example, conductive vias 28, 32, 36 and conductive traces 30, 34 can be connected to provide an electrical connection between corresponding locations on the upper and lower surfaces of the laminate substrate 10.

In the example of FIG. 1, the semiconductor die 14 is shown to allow electrical connections only on the upper side. Accordingly, electrical connections between locations above and below the semiconductor die 14 need to be routed around the semiconductor die 14. Thus, if the size of the semiconductor die 14 is relatively large compared to the overall size of the laminate substrate 10, there can be internal routing challenges, including those associated with grounding and/or non-grounding connections.

FIG. 2 shows another example of a laminate substrate 50 having a device 52 embedded in one or more laminate layers 12. Such a device (52) can be similar to the device 14 of FIG. 1, but with a backside metal layer 54 (on the lower side when shown as in FIG. 2). However, such a backside metal layer typically has only one polarity, usually ground. Accordingly, the backside metal layer 54 is shown to be electrically connected to one or more grounding pads (not shown in FIG. 2) through, for example, a plurality of conductive vias 56. In FIG. 2, example conductive paths through the laminate substrate 50 and example connections above the embedded device 52 can be similar to the example of FIG. 1.

In the example of FIG. 2, the embedded device 52 is shown to allow electrical connections on the upper side, and grounding connections on the lower side. Accordingly, non-grounding electrical connections between locations above and below the embedded device 52 need to be routed around the embedded device 52, similar to the example of FIG. 1. Thus, if the size of the embedded device 52 is relatively large compared to the overall size of the laminate substrate 50, there can be internal routing challenges, including those associated with grounding and/or non-grounding connections.

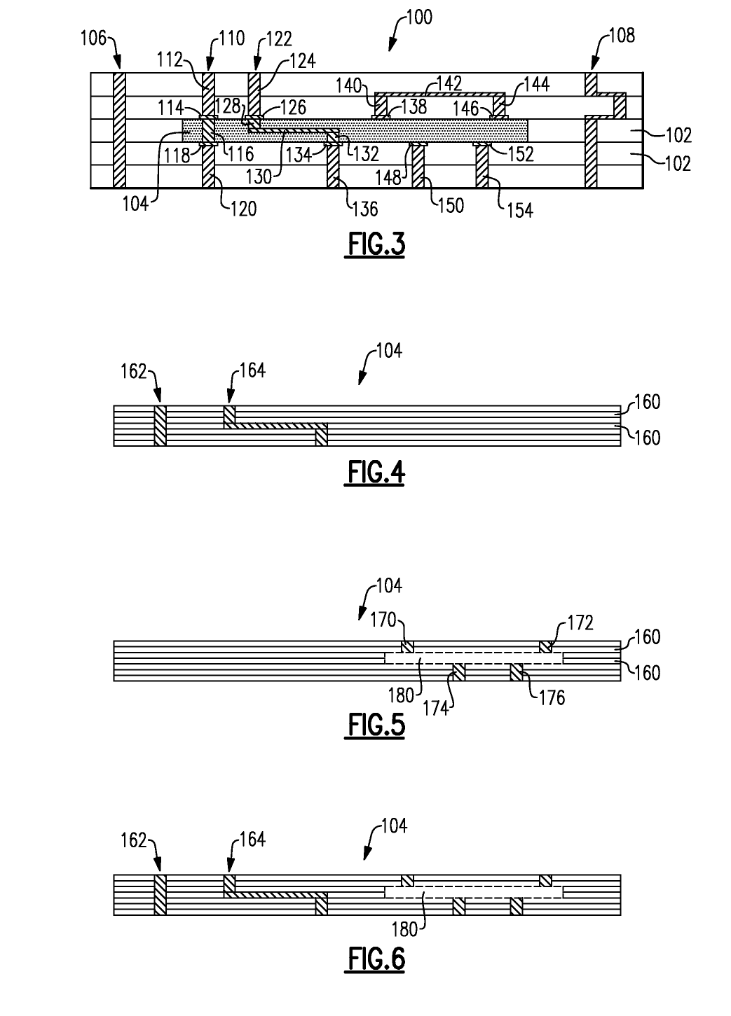

FIG. 3 shows that in some embodiments, a laminate substrate 100 can include a device 104 embedded in one or more laminate layers 102. As described herein, such a device (104) can be configured to allow electrical connections on both sides. In some embodiments, such electrical connections can include non-grounding connections on both sides of the device 104.

In some embodiments, the device 104 can include one or more internal paths configured to facilitate one or more electrical connections between locations above (e.g., on the upper surface of the laminate substrate 100) and below (e.g. on the lower surface of the laminate substrate 100) the embedded device 104. Examples of such internal path in the embedded device 104 are described herein in greater detail.

In the example of FIG. 3, contact pads 114, 126, 138, 146 are shown to be provided on the upper side of the device 104, and contact pads 118, 134, 148, 152 are shown to be provided on the lower side of the device 104. An example internal path 116 (e.g., a conductive via) is shown to electrically connect the example contact pads 114, 118 above and below the device 104. The upper contact pad 114 is shown to be electrically connected to a location on the upper surface of the laminate substrate 100 through an example conductive via 112, and the lower contact pad 118 is shown to be electrically connected to a location on the lower surface of the laminate substrate 100 through an example conductive via 120. Accordingly, a conductive path 110 between the upper and lower surfaces of the laminate substrate 100 is shown to pass through the embedded device 104.

Another example internal path that includes paths 128 (e.g., a conductive via), 130 (e.g., a conductive trace), and 132 (e.g., a conductive via) is shown to electrically connect the example contact pads 126, 134 above and below the device 104. The upper contact pad 126 is shown to be electrically connected to a location on the upper surface of the laminate substrate 100 through an example conductive via 124, and the lower contact pad 134 is shown to be electrically connected to a location on the lower surface of the laminate substrate 100 through an example conductive via 136. Accordingly, a conductive path 122 between the upper and lower surfaces of the laminate substrate 100 is shown to pass through the embedded device 104.

In the example of FIG. 3, the conductive paths 110, 122 facilitated by the respective internal paths in the embedded device 104 can be utilized for non-grounding connections, grounding connections, or any combination thereof.

In the example of FIG. 3, paths 140 (e.g., a conductive via), 142 (e.g., a conductive trace), and 144 (e.g., a conductive via) is shown to electrically connect the contact pads 138, 146 above the device 104. Such a conductive path can be utilized to electrically connect two locations within the device 104.

In the example of FIG. 3, the contact pad 148 on the lower side of the device 104 is shown to be electrically connected to a location on the lower surface of the laminate substrate 100 through an example conductive via 150. Similarly, the contact pad 152 on the lower side of the device 104 is shown to be electrically connected to a location on the lower surface of the laminate substrate 100 through an example conductive via 154. Such conductive paths between the device 104 and the lower surface of the laminate substrate 100 can be utilized for non-grounding connections, grounding connections, or any combination thereof.

In the example of FIG. 3, conductive paths 106, 108 are shown to provide electrical connections between their respective locations on the upper and lower surfaces of the laminate substrate 100. Such conductive paths can be similar to the example conductive paths 22, 26 described in reference to FIG. 1.

In some embodiments, the embedded device 104 of FIG. 3 can be a ceramic device such as a co-fired ceramic device (e.g., a low-temperature co-fired ceramic (LTCC) device). Such an LTCC device can be implemented as a relatively thin LTCC substrate capable of having connections on both sides. Such a combination of features can allow the LTCC device to be embedded in part of a layer, and/or one or more layers of a laminate substrate, and also allow electrical path(s) to be implemented through the LTCC. It is also noted that a thin LTCC (e.g., about 100 μm thickness) typically has less processing issues than a thin die (e.g., about 100 μm thickness). Accordingly, use of an LTCC as a device embedded in a laminate substrate can address many of the issues and limitations associated with use of an embedded die such as an IPD in laminate technology.

Various examples are described herein in the context of the embedded device (e.g., 104 in FIG. 3) being a ceramic device such as an LTCC device. It will be understood that other types of ceramic devices such as, for example, a high-temperature co-fired ceramic (HTCC) device, can also be configured and embedded as described herein.

FIGS. 4-6 show examples of an LTCC substrate 104 that can be embedded in a laminate substrate as described in reference to FIG. 3. Such an LTCC substrate 104 can include a plurality of layers 160 stacked and fired together. FIG. 4 shows that in some embodiments, an LTCC substrate 104 can be configured to include one or more conductive paths (e.g., 162, 164) implemented between upper and lower surfaces of the LTCC substrate 104. As described in reference to FIG. 3, such conductive path(s) can allow formation of a conductive path in the laminate substrate without having to route around the embedded LTCC substrate 104.

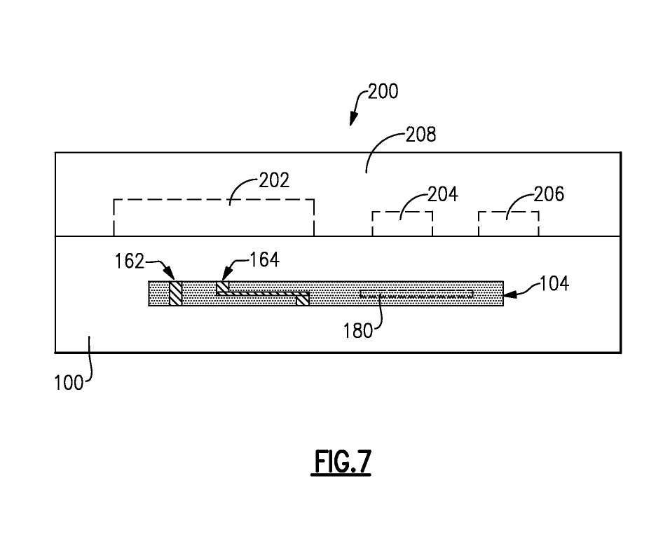

FIG. 5 shows that in some embodiments, an LTCC substrate 104 can be configured to allow electrical connections on both sides of the LTCC substrate 104. In the example of FIG. 5, conductive paths 170, 172 (e.g., conductive vias) are shown to provide electrical connections between the upper surface of the LTCC substrate 104 and a circuit 180. Further, conductive paths 174, 176 (e.g., conductive vias) are shown to provide electrical connections between the lower surface of the LTCC substrate 104 and the circuit 180. As described herein, such a circuit can be configured as, for example, a filter circuit. In some embodiments, the conductive features 170, 172, 174, 176 can be utilized to provide non-grounding connection(s), grounding connection(s), or some combination thereof. Such connections can be, for example, between the circuit 180 and upper surface and/or lower surface of the LTCC substrate 104, between different locations of the circuit 180, or some combination thereof.

FIG. 6 shows that in some embodiments, an LTCC substrate 104 can be configured to include both functionalities described in reference to FIGS. 4 and 5. Such a configuration can provide advantageous features for a laminate substrate having the LTCC substrate 104 embedded therein.

FIG. 7 shows a radio-frequency (RF) module 200 that includes a packaging substrate 100 having one or more features as described herein. In some embodiments, the packaging substrate 100 can be a laminate substrate as described herein, and can include an embedded device 104 such as an LTCC substrate 104 also as described herein. The example LTCC substrate 104 is depicted as having conductive paths 162, 164 between its upper and lower surfaces, as well as a circuit 180 electrically connected to either or both of the upper and lower surfaces. It will be understood that the LTCC substrate 104 can be configured with some of all of such features, as described in reference to FIGS. 4-6.

In the example of FIG. 7, the RF module 200 can include one or more die (depicted as 202) having an RF circuit, and one or more SMT components (depicted as 204, 206), mounted on the laminate substrate 100. As described herein, the embedded LTCC substrate 104 can operate in conjunction with the RF circuit and the SMT component(s). As also described herein, the embedded LTCC substrate 104 can provide advantageous connectivity for such components mounted on the laminate substrate 100.

In the example of FIG. 7, the RF module 200 can further include an overmold 208 that encapsulates some or all of the components mounted on the upper surface of the laminate substrate 100. Although not shown in FIG. 7, the RF module 200 can also include RF shielding features.

For example, shielding wirebonds can be implemented on the laminate substrate 100 and be encapsulated by the overmold 208, and a conductive layer can be implemented over the overmold 208, so as to provide shielding functionality. Among others, additional details concerning such a shielding configuration can be found in U.S. Pat. No. 9,071,335 entitled RADIO-FREQUENCY MODULES HAVING TUNED SHIELDING-WIREBONDS, which is expressly incorporated by reference in its entirely.

In another example, a conformal shielding layer can be implemented on the upper surface of the overmold 208 and the side walls of the overmold 208 and the laminate substrate 100. In the context of such a conformal shielding, the RF module may or may not include the overmold 208. Among others, additional details concerning such a shielding configuration can be found in U.S. patent application Ser. No. 14/839,975 entitled DEVICES AND METHODS RELATED TO METALLIZATION OF CERAMIC SUBSTRATES FOR SHIELDING APPLICATIONS, which is expressly incorporated by reference in its entirely.

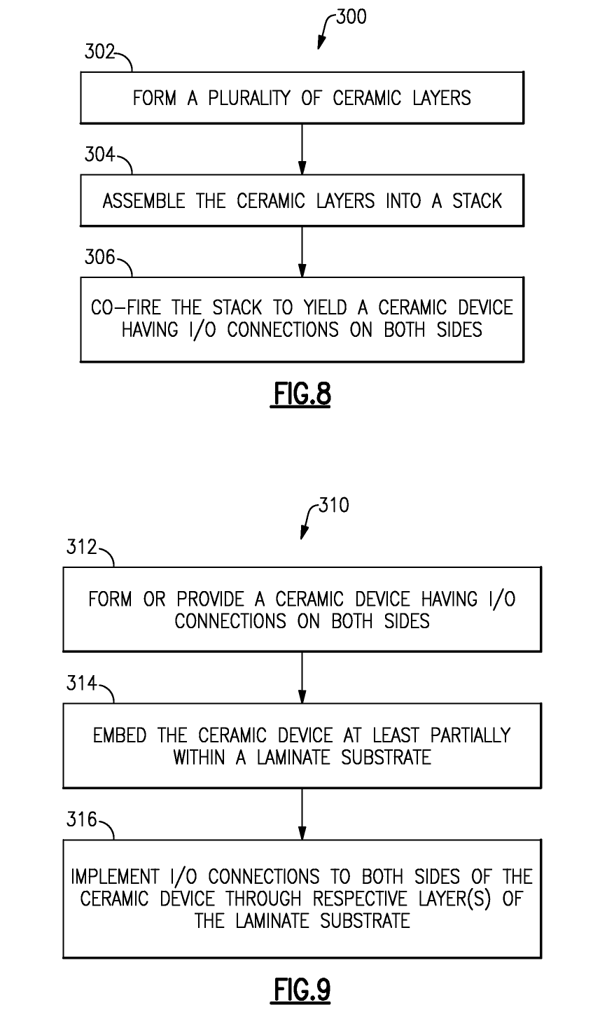

FIG. 8 shows a process 300 that can be implemented to fabricate a ceramic device such as an LTCC substrate having one or more features as described herein. In block 302, a plurality of ceramic layers can be formed or provided. In block 304, the ceramic layers can be assembled into a stack. In block 306, the stack of ceramic layers can be co-fired to yield a ceramic device having input/output connections on both sides and/or one or more electrical connections through the stack of ceramic layers.

In some embodiments, the ceramic layers assembled in the stack can include an array of units to be singulated into individual units, with each individual unit to be embedded into a laminate substrate. In such an application, the ceramic layers in the stack can be in a green form so as to facilitate fabrication of the layers. Singulation can also occur while the ceramic layers are in the green form. The singulated units can be fired so as to yield the co-fired individual units.

FIG. 9 shows a process 310 that can be implemented to fabricate a laminate substrate having one or more features as described herein. In block 312, a ceramic device having input/output connections on both sides and/or one or more electrical connections through the ceramic device can be formed or provided. In block 314, the ceramic device can be embedded at least partially within a laminate substrate. In block 316, input/output connections to both sides of the ceramic device can be implemented through respective layer(s) of the laminate substrate.

In some embodiments, embedding of the ceramic devices and implementing of the input/output connections for the ceramic devices can be implemented in an array format. In such a format, a panel of laminate substrate can be fabricated, with the panel including an array of units, where each unit has an embedded LTCC substrate and related electrical connections as described herein. Such a panel can be utilized to mass produce RF modules in an array format, and such RF modules can be singulated when partially or fully completed.

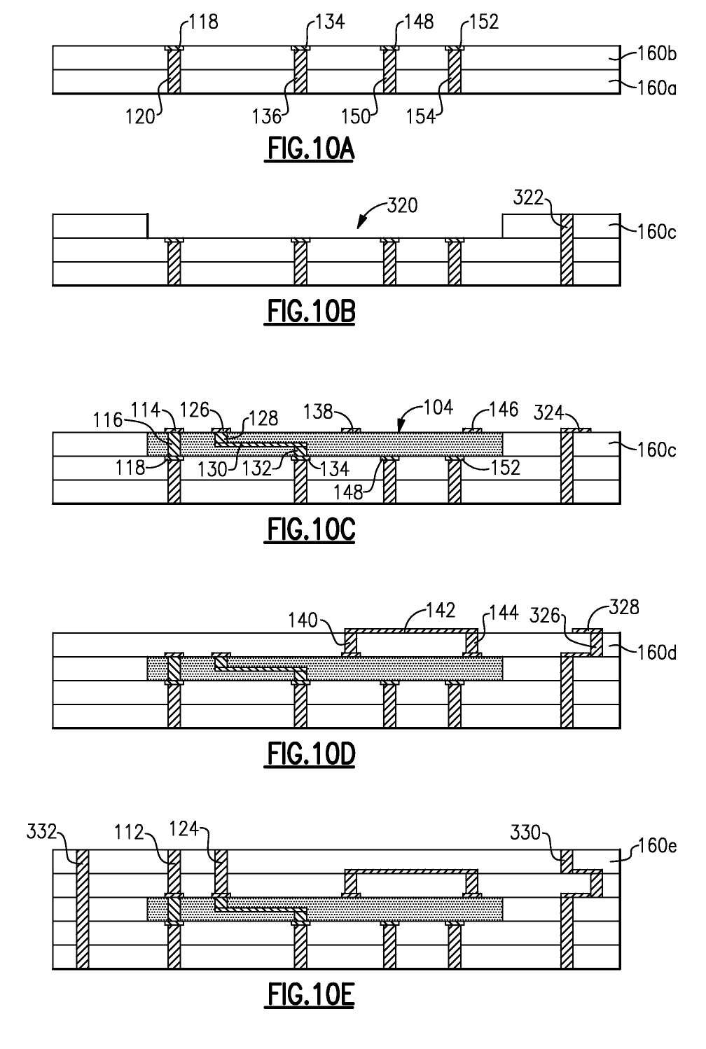

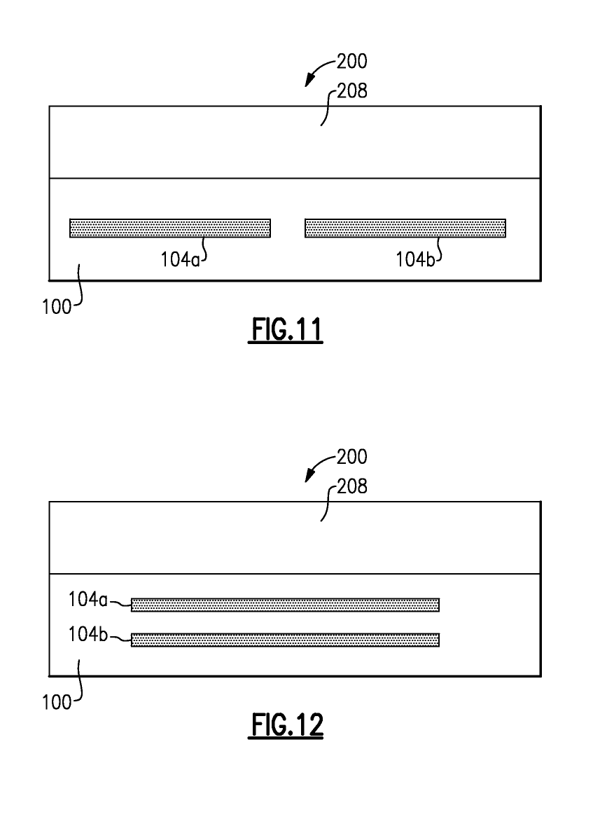

FIGS. 10A-10E show examples of various stages of the laminate substrate fabrication process described in reference to FIG. 9, in the context of the example configuration of FIG. 3. Although a single unit of laminate substrate is depicted, it will be understood that such a fabrication process can be implemented in a panel format. It will also be understood that, although the laminate substrate is described as having five layers, other numbers of layers can also be implemented.

In FIG. 10A, first and second layers 160a, 160b are shown to be formed and arranged in a partial stack. Further, conductive vias 120, 136, 150, 154 and their respective contact pads 118, 134, 148, 152 are shown to be formed.

In FIG. 10B, a third layer 160c is shown to be arranged over the second layer 160b. The third layer 160c is shown to include an opening 320 dimensioned to receive an LTCC substrate as described herein. Further, a conductive via 322 is shown to be formed so as to extend through the three layers.

In FIG. 10C, an LTCC substrate 104 is shown to be embedded in the opening 320 of the third layer 160c. As described herein, the LTCC substrate 104 can include conductive paths between its upper and lower sides. For example, a conductive via 116 can form such a path. In another example, a conductive via 128, a conductive trace 130, and a conductive via 132 can also form such a path. On the underside of the LTCC substrate 104, the contact pads 118, 134 are shown to facilitate electrical connections between such two example paths to their respective conductive vias (120, 136 in FIG. 10A). On the upper side of the LTCC substrate 104, contact pads 114, 126 are shown to be formed to facilitate electrical connections between such two example paths and their respective locations above the LTCC substrate 104.

In FIG. 10C, the contact pads 148, 152 are shown to facilitate further electrical connections on the underside of the LTCC substrate 104. Similarly, contact pads 138, 146 are shown to facilitate further electrical connections on the upper side of the LTCC substrate 104. In some embodiments, such connections associated with the contact pads 138, 146, 148, 152 can be utilized to provide connections for a circuit within the LTCC substrate 104, as described in reference to FIG. 6.

In FIG. 100, a conductive trace 324 is shown to be formed on the third layer 160 and in contact with the conductive via 322.

In FIG. 10D, a fourth layer 160d is shown to be arranged over the third layer 160c and the LTCC substrate 104. Conductive vias 140, 144, 326 are shown to be formed in the fourth layer 160d. The conductive vias 140, 144 are shown to be connected through a conductive trace 142. The conductive via 326 is shown to be connected to the conductive trace 324 on the third layer 160c, as well as a conductive trace 328 on the fourth layer 160d.

In FIG. 10E, a fifth layer 160e is shown to be arranged over the fourth layer 16d so as to form a complete laminate substrate. A conductive via 330 is shown to be formed in the fifth layer 160e so as to be connected to the conductive trace 328 on the fourth layer 160d, thereby completing a conductive path between the upper and lower surfaces of the laminate substrate. A conductive via 332 is shown to be formed through all of the five layers, to thereby form another conductive path between the upper and lower surfaces of the laminate substrate. Conductive vias 112, 124 are shown to be formed through the fourth and fifth layers 160d, 160e, so as to connect the contact pads 114, 126 (FIG. 10C) to their respective locations on the upper side of the laminate subtrate.

In the various example stages of FIGS. 10A-10E, some of the vias are described as being formed through one or more layers. It will be understood that such vias can be pre-formed for each layer and stacked, formed after being stacked, or any combination thereof.

In the various examples described above, a laminate substrate 100 is depicted as including a single device 104 embedded in one or more laminate layers 102. However, it will be understood that a laminate substrate can include a plurality of devices, such as ceramic devices, embedded in one or more laminate layer.

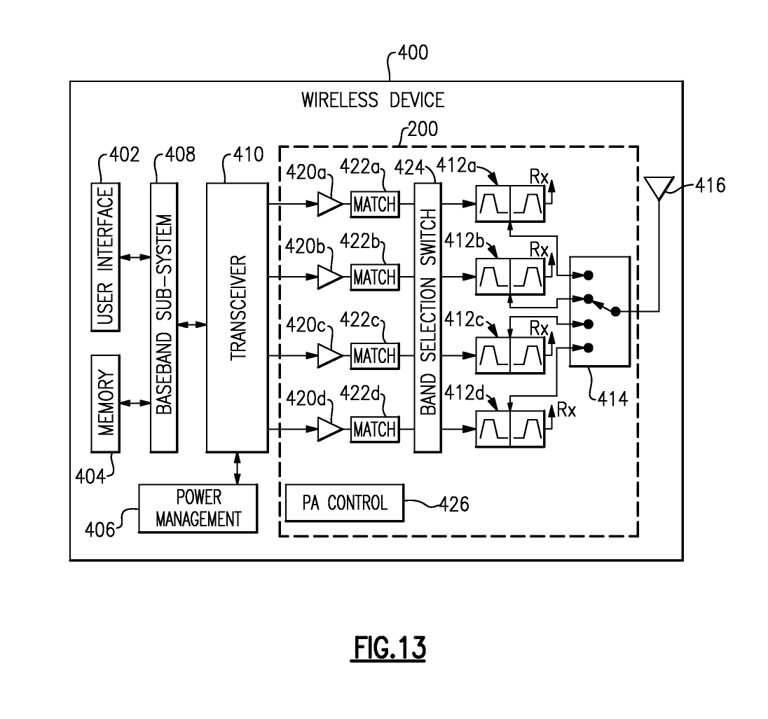

For example, FIG. 11 shows an example module 200 (e.g., an RF module) having a laminate substrate 100 and one or more components mounted thereon. Such component(s) can be substantially encapsulated by an overmold 208, similar to the example configuration of FIG. 7. In some embodiments, such a laminate substrate 100 can include a plurality of ceramic devices (e.g., 104a, 104b) embedded therein. Such ceramic devices can be arranged in, for example, a laterally offset manner. Such ceramic devices may or may not be implemented in the same laminate layer of the laminate substrate 100.

In another example, FIG. 12 shows an example module 200 (e.g., an RF module) having a laminate substrate 100 and one or more components mounted thereon. Such component(s) can be substantially encapsulated by an overmold 208, similar to the example configuration of FIG. 7. In some embodiments, such a laminate substrate 100 can include a plurality of ceramic devices (e.g., 104a, 104b) embedded therein. Such ceramic devices can be arranged in, for example, a vertically offset manner. Such ceramic devices can be implemented in different laminate layers of the laminate substrate 100, and may or may not overlap (partially or fully) with each other.

In the examples of FIGS. 11 and 12, it will be understood that a given set of ceramic devices may or may not be dimensioned the same. Further, in each of the examples of FIGS. 11 and 12, both of the ceramic devices 104 are depicted as being similar to the example ceramic devices described in reference to FIGS. 3-7. However, it will be understood that in some embodiments, some may be similar to such ceramic devices (e.g., 104 in FIGS. 3-7), while other(s) can be similar to the example embedded device configurations of FIGS. 1 and/or 2.

In some implementations, a device having one or more features described herein can be included in an RF device such as a wireless device. Such a device can be implemented in, for example, a modular form as described herein. In some embodiments, such a wireless device can include, for example, a cellular phone, a smart-phone, a hand-held wireless device with or without phone functionality, a wireless tablet, etc.

FIG. 13 depicts an example wireless device 400 having one or more advantageous features described herein. In the context of a module having one or more features as described herein, such a module can be generally depicted by a dashed box 200, and can be implemented as a front-end module (FEM). It will be understood that a module having one or more features as described herein can be implemented to include other portions of the wireless device 400.

In the example of FIG. 13, power amplifiers (PAs) 420 can receive their respective RF signals from a transceiver 410 that can be configured and operated to generate RF signals to be amplified and transmitted, and to process received signals. Operation of the PAs 420 can be facilitated by a PA control component 426.

The transceiver 410 is shown to interact with a baseband sub-system 408 that is configured to provide conversion between data and/or voice signals suitable for a user and RF signals suitable for the transceiver 410. The transceiver 410 is also shown to be connected to a power management component 406 that is configured to manage power for the operation of the wireless device. Such power management can also control operations of the baseband sub-system 408 and the module 200.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, outputs of the PAs 420 are shown to be matched (via respective match circuits 422) and routed to an antenna 416 through a band selection switch 424, their respective duplexers 412 and an antenna switch 414. In some embodiments, each duplexer 412 can allow transmit and receive operations to be performed simultaneously using a common antenna (e.g., 416). In FIG. 13, received signals are shown to be routed to “Rx” paths that can include, for example, one or more low-noise amplifiers (LNAs).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A laminate substrate comprising:
a plurality of laminate layers; and
a ceramic device having a first side and a second side, and embedded at least partially within the plurality of laminate layers, the ceramic device including a conductive path between the first side and the second side.

2. The laminate substrate of claim 1 wherein the first and second sides of the ceramic device face upper and lower sides of the plurality of laminate layers, respectively.

3. The laminate substrate of claim 2 wherein the ceramic device is a low-temperature co-fired ceramic (LTCC) device or a high-temperature co-fired ceramic (HTCC) device.

4. The laminate substrate of claim 3 wherein the ceramic device includes more than two ceramic layers including an upper ceramic layer, a lower ceramic layer, and at least one intermediate ceramic layer, the upper and lower ceramic layers facing the upper and lower sides of the plurality of laminate layers, respectively.

5. The laminate substrate of claim 4 wherein the conductive path includes a conductive via that extends through all of the ceramic layers.

6. The laminate substrate of claim 4 wherein the conductive path includes a plurality of laterally offset conductive vias electrically connected by one or more conductive traces.

7. The laminate substrate of claim 2 wherein the conductive path is substantially within the ceramic device.

8. The laminate substrate of claim 2 wherein the plurality of laminate layers includes a conductive path that bypasses the ceramic device.

9. The laminate substrate of claim 2 wherein the ceramic device includes electrical connection features on both of the first and second sides.

10. The laminate substrate of claim 9 wherein at least some of the electrical connection features on the first side of the ceramic device is configured to facilitate a non-grounding connection.

11. The laminate substrate of claim 10 wherein at least some of the electrical connection features on the second side of the ceramic device is configured to facilitate a non-grounding connection.

12. The laminate substrate of claim 9 wherein two or more of the electrical connection features are configured to facilitate an electrical connection between different locations on the ceramic device.

13. The laminate substrate of claim 12 wherein the electrical connection between the different locations on the ceramic device further includes a conductive path through one or more of the plurality of laminate layers.

14. The laminate substrate of claim 2 wherein the laminate substrate is a packaging substrate configured to receive a plurality of components.

15. A radio-frequency (RF) module comprising:
a packaging substrate having a plurality of laminate layers and a ceramic device embedded at least partially within the plurality of laminate layers, the ceramic device including an internal conductive path configured to facilitate an electrical connection between locations above and below the ceramic device without having to route the electrical connection around the ceramic device; and
one or more RF components mounted on the packaging substrate.

16. The RF module of claim 15 wherein the ceramic device further includes a circuit configured to operate in conjunction with the one or more RF components.

17. The RF module of claim 16 wherein the circuit includes a filter circuit.

18. The RF module of claim 15 further comprising an overmold structure implemented over the packaging substrate, the overmold structure configured to encapsulate the one or more RF components.

19. The RF module of claim 18 further comprising one or more RF shielding features implemented relative to the one or more RF components.

20. A method for fabricating a radio-frequency (RF) module, the method comprising:
forming or providing a packaging substrate having a plurality of laminate layers and a ceramic device embedded at least partially within the plurality of laminate layers, the ceramic device including an internal conductive path configured to facilitate an electrical connection between locations above and below the ceramic device without having to route the electrical connection around the ceramic device; and
mounting one or more RF components on the packaging substrate.
